(19) United States
(12) Patent Application Publication
(10) Pub. No.: US 2026/0310271 A1
(43) Pub. Date: Oct. 8, 2026

(54) POWER DISTRIBUTION ARCHITECTURE FOR GPU ACCELERATOR ARRAY SYSTEMS

(71) Applicant: NVIDIA Corporation, Santa Clara, CA (US)

(72) Inventors: Yaoyu Tsai, Fremont, CA (US); Mattia Balutto, Cupertino, CA (US); Tim Lee, San Francisco, CA (US); Changpeng Song, Yorba Linda, CA (US)

(21) Appl. No.: 19/170,186

(22) Filed: Apr. 4, 2025

(51) Int. Cl. G06F 1/26; H05K 7/14

(52) U.S. Cl. CPC G06F 1/26; H05K 7/1492

(57) ABSTRACT

Power supply and distribution architectures, e.g., for supplying and distributing power to a GPU accelerator array of a data center server. In at least one embodiment, a power supply and distribution architecture includes a power distribution board having both a power converter for converting a supply voltage of a power supply to an operating voltage of a GPU and a GPU power connector for transmitting power to the GPU at the operating voltage.

### FIELD

The present disclosure relates to power supply and distribution architectures, e.g., for a GPU accelerator array of a data center server. In at least one embodiment, a power supply and distribution architecture includes a power distribution board having both a power converter for converting a supply voltage of a power supply to an operating voltage of a GPU and a GPU power connector for transmitting power to the GPU at the operating voltage.

### BACKGROUND

Modern multi-Graphics Processing Unit (GPU) data center server systems require specialized power supply solutions to meet the extreme demands of high performance computing (HPC), e.g., artificial intelligence (AI) workload acceleration. Such power supply solutions often employ multiple high-wattage power supply units (PSUs) in parallel configurations to support dense arrays of GPU accelerators while maintaining redundancy. Power distribution is a key consideration. Power Distribution Boards (PDBs) and synchronization adapters can be used to coordinate multiple PSUs safely. Voltage scaling is also crucial. Higher voltage power supplies are capable of meeting increased power demands while maintaining efficiency. Energy density is another critical factor, enabled by high-efficiency PSU designs and advanced cooling solutions.

Emerging solutions focus on standardization and efficiency improvements. Modular server architectures demonstrate scalable power designs supporting numerous GPUs with multiple CRPS power supplies. Advanced materials like Gallium nitride (GaN) and silicon carbide (SiC) power integrated circuits (ICs) that enable high efficiency power supply units (PSUs) while reducing thermal loads. Smart power management features, including Power Management Bus (PMBus) monitoring and rapid-response autonomous protection circuits, ensure stable operation, e.g., for AI training workloads that cannot tolerate interruption. These innovations aim to balance the AI industry's explosive computational growth with sustainable energy usage as data centers become major consumers of electricity.

### BRIEF DESCRIPTION OF THE DRAWINGS

Subject matter of the present disclosure is described in detail below with reference to the attached drawing FIGURES. Features described and/or illustrated herein can be used alone and/or combined in different combinations. The attached drawings illustrate the following:

FIG. 1A is a perspective view of a data center server, in accordance with an embodiment.

FIG. 1B is a top view of the data center server of FIG. 1A.

FIG. 1C is a perspective view of certain components of a power supply and distribution architecture of the data center server of FIG. 1A.

FIG. 2 is a block diagram of a power supply and distribution architecture, in accordance with an embodiment.

FIG. 3 illustrates a parallel processing unit, in accordance with an embodiment.

FIG. 4A illustrates a general processing cluster within the parallel processing unit of FIG. 3, in accordance with an embodiment.

FIG. 4B illustrates a memory partition unit of the parallel processing unit of FIG. 3, in accordance with an embodiment.

FIG. 5A illustrates the streaming multi-processor of FIG. 4A, in accordance with an embodiment.

FIG. 5B is a conceptual diagram of a processing system implemented using the PPU of FIG. 3, in accordance with an embodiment.

FIG. 5C illustrates an exemplary system in which the various architecture and/or functionality of the various previous embodiments may be implemented.

FIG. 6 is a conceptual diagram of a graphics processing pipeline implemented by the PPU of FIG. 3, in accordance with an embodiment.

### DETAILED DESCRIPTION

In the following description, various embodiments will be described. For purposes of explanation, specific configurations and details are set forth in order to provide a thorough understanding of the embodiments. However, it will also be apparent to one skilled in the art that the embodiments may be practiced without the specific details. Furthermore, well-known features may be omitted or simplified in order not to obscure the embodiment being described.

The systems and methods described herein may be used by, without limitation, non-autonomous vehicles, semi-autonomous vehicles (e.g., in one or more advanced driver assistance systems (ADAS)), piloted and un-piloted robots or robotic platforms, warehouse vehicles, off-road vehicles, vehicles coupled to one or more trailers, flying vessels, boats, shuttles, emergency response vehicles, motorcycles, electric or motorized bicycles, aircraft, construction vehicles, trains, underwater craft, remotely operated vehicles such as drones, and/or other vehicle types. Further, the systems and methods described herein may be used for a variety of purposes, by way of example and without limitation, for machine control, machine locomotion, machine driving, synthetic data generation, model training or updating, perception, augmented reality, virtual reality, mixed reality, robotics, security and surveillance, simulation and digital twinning, autonomous or semi-autonomous machine applications, deep learning, environment simulation, object or actor simulation and/or digital twinning, data center processing, conversational AI, generative AI, light transport simulation (e.g., ray-tracing, path tracing, etc.), collaborative content creation for 3D assets, cloud computing and/or any other suitable applications.

Disclosed embodiments may be comprised in a variety of different systems such as automotive systems (e.g., a control system for an autonomous or semi-autonomous machine, a perception system for an autonomous or semi-autonomous machine), systems implemented using a robot, aerial systems, medical systems, boating systems, smart area monitoring systems, systems for performing deep learning operations, systems for performing simulation operations, systems for performing digital twin operations, systems implemented using an edge device, systems incorporating one or more virtual machines (VMs), systems for performing synthetic data generation operations, systems implemented at least partially in a data center, systems for performing conversational AI operations, systems for performing generative AI operations, systems implemented using large language models (LLMs), systems implemented using vision language models (VLMs), systems for performing light transport simulation, systems for performing collaborative content creation for 3D assets, systems implemented at least partially using cloud computing resources, and/or other types of systems.

Systems and methods are disclosed related to power supply and distribution architectures, e.g., for multi-GPU accelerator arrays. According to one or more embodiments, a power supply supplies power at a supply voltage that exceeds an operating voltage of one or more GPUs, and at least one power converter converts the supply voltage to an operating voltage. According to one or more embodiments, the at least one power converter is co-located with at least one GPU power connector configured to transmit power, at the operating voltage, directly to one or more GPUs (e.g., of a multi-GPU accelerator array). In one or more embodiments, the at least one power converter and the at least one GPU power connector are co-located at a mid-chassis Power Distribution Board (PDB) of a chassis of a modular data center server. By co-locating the power converter and the GPU power connectors at a mid-chassis PDB, power can be transported from one or more power supplies to the mid-chassis PDB at the higher supply voltage rather than the lower operating voltage, thereby significantly reducing current. As a result, relatively small and light transmission lines/busbars can be used without causing excess transmission losses or heat generation and without negatively impacting the longevity and reliability of the power distribution architecture. Furthermore, spatial constraints and thermal management constraints can simultaneously be satisfied.

According to one or more embodiments, a power distribution architecture includes a mid-chassis PDB for supplying power to one or more GPUs, e.g., of a multi-GPU accelerator array of a modular data center server. In one or more embodiments, the mid-chassis PDB includes a power converter configured to convert a supply voltage to an operating voltage of the one or more GPUs. In one or more embodiments, the power converter includes one or more dual-regulated hybrid switched capacitor (DR-HSC) power converters. In one or more embodiments, the mid-chassis PDB further includes one or more GPU power connection interfaces configured to supply power, at the operating voltage, directly to the one or more GPUs.

According to one or more embodiments, a power supply system for supplying power to one or more GPUs, e.g., of a multi-GPU accelerator array of a modular data center server, includes one or more power supplies configured to supply power at a supply voltage and a power distribution architecture configured to transmit the supplied power to the one or more GPUs. In one or more embodiments, the power supply system includes a mid-chassis PDB. In one or more embodiments, the mid-chassis PDB includes a power converter configured to convert the supply voltage to an operating voltage of the one or more GPUs. In one or more embodiments, the power converter includes one or more DR-HSC power converters. In one or more embodiments, the mid-chassis PDB further includes one or more GPU power connection interfaces configured to supply power, at the operating voltage, directly to the one or more GPUs.

According to one or more embodiments, a modular data center server includes a multi-GPU accelerator array and a power supply system for supplying power to the multi-GPU accelerator array. The power supply system includes one or more power supplies configured to supply power at a supply voltage (e.g., of 54V or 48V) and a power distribution architecture configured to transmit the supplied power to the multi-GPU accelerator array. In one or more embodiments, the power supply system includes a mid-chassis Power Distribution Board (PDB). In one or more embodiments, the mid-chassis Power Distribution Board (PDB) includes a power converter configured to convert the supply voltage to an operating voltage (e.g., 12V) of the GPUs of the multi-GPU accelerator array. In one or more embodiments, the power converter includes one or more DR-HSC power converters. In one or more embodiments, the mid-chassis PDB further includes one or more GPU power connection interfaces configured to supply power, at the operating voltage, directly to GPUs of the multi-GPU accelerator array.

According to one or more embodiments, a power distribution board (PDB), e.g., for a data center server, includes a supply input unit to receive power at a supply voltage, a power converter to convert the power received at a supply voltage to an operating voltage of a graphics processing unit (GPU), and one or more GPU power connectors, to provide power directly to one or more GPUs at the operating voltage.

According to an embodiment of the PDB, the PDB is a mid-chassis PDB configured to be mounted in a middle region of a data center server chassis.

According to an embodiment of the PDB, the power converter comprises a dual-regulated, hybrid switched capacitor (DR-HSC).

According to an embodiment of the PDB, the PDB further includes a GPU interconnect board power connector, configured to provide power directly to a GPU interconnect board at the operating voltage.

According to an embodiment of the PDB, the supply voltage is greater than or equal to 48V and the operating voltage is less than or equal to 12V.

According to an embodiment of the PDB, the one or more GPU power connectors include a blade power connector and/or a pin power connector. According to an embodiment, the pin power connector is a PCI Express (PCIe) 5.0 CEM (Card Electromechanical) (“CEM5”) pin power connector.

According to one or more embodiments, a power supply and distribution system, e.g., for a data center server, includes the aforementioned power distribution board (PDB) or any embodiment thereof. The power supply and distribution system further includes one or more power supply units (PSUs) to supply the power at the supply voltage and one or more busbars to transmit the power at the supply voltage to the PDB.

According to an embodiment of the power supply and distribution system, a PSU of the one or more PSUs includes a power supply PDB and one or more common redundant power supplies (CRPSs) to supply power at the supply voltage and connected to the power supply PDB.

According to an embodiment of the power supply and distribution system, a CRPS of the one or more CRPSs is configured to receive alternating current (AC) power from one or more external power distribution units (PDUs) and to supply the power at the supply voltage by converting the AC power to direct current (DC) power at the supply voltage.

According to an embodiment of the power supply and distribution system, the received AC power has a distribution voltage of 230V or higher.

According to one or more embodiments, a server includes the aforementioned power supply and distribution system or any embodiment thereof and one or more GPUs.

According to an embodiment of the server, the one or more GPUs have an aggregated total board power (TBP) and the one or more busbars have an aggregated cross-sectional area, wherein a ratio of the aggregated cross-sectional area to the aggregated TBP is less than 10 mm²/kW. According to an embodiment, the ratio of the aggregated cross-sectional area to the aggregated TBP is less than 8 mm²/kW. According to an embodiment, the ratio of the aggregated cross-sectional area to the aggregated TBP is in a range of 4.5 mm²/kW to 8 mm²/kW.

According to one or more embodiments, the server is included in at least one of: a control system for an autonomous or semi-autonomous machine; a perception system for an autonomous or semi-autonomous machine; a system for performing simulation operations; a system for performing digital twin operations; a system for performing light transport simulation; a system for performing collaborative content creation for 3D assets; a system for performing deep learning operations; a system implemented using an edge device; a system implemented using a robot; a system for performing conversational AI operations; a system for generating synthetic data; a system incorporating one or more virtual machines (VMs); a system implemented at least partially in a data center; or a system implemented at least partially using cloud computing resources.

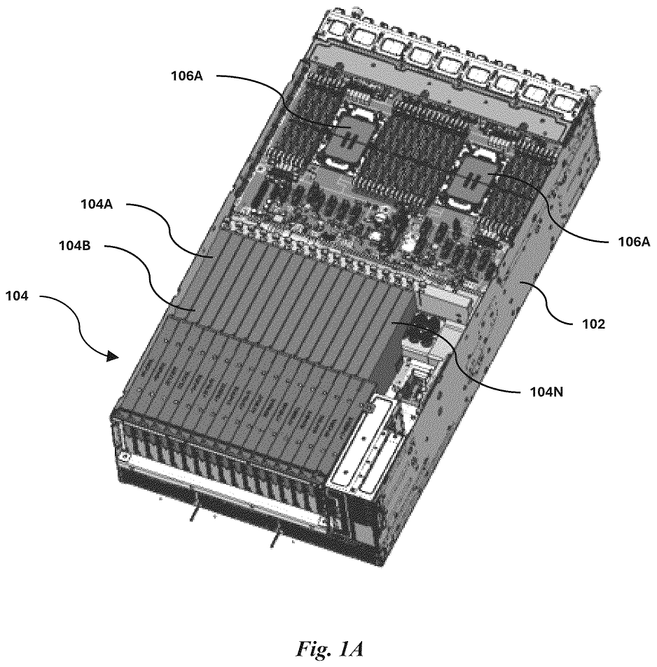

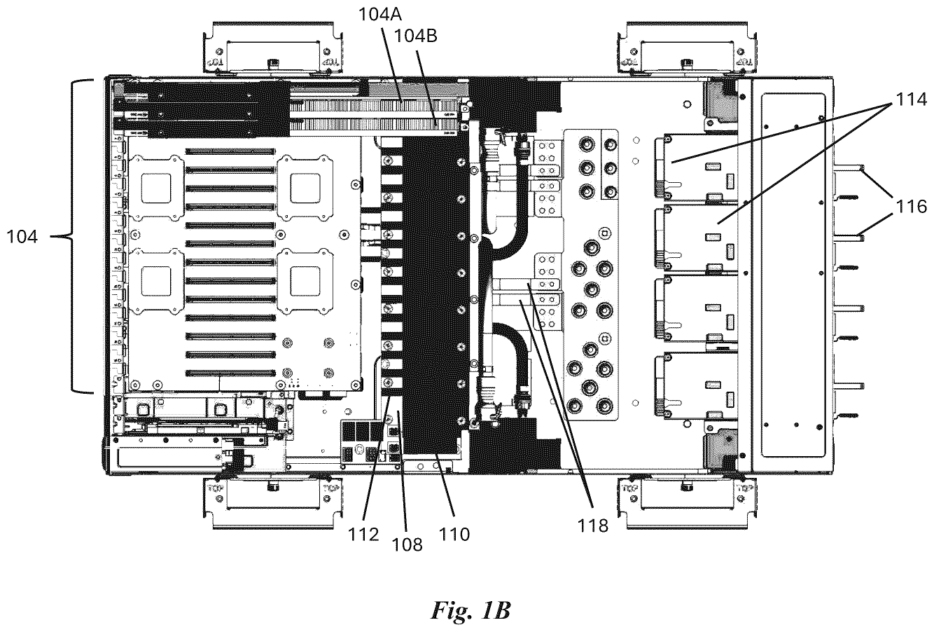

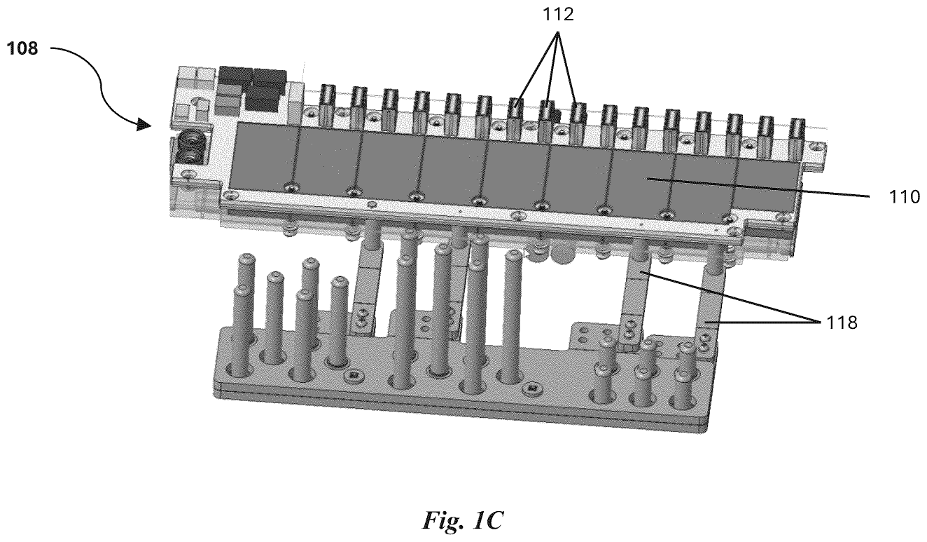

FIG. 1A is a perspective view of a data center server 100 in accordance with one or more embodiments. It should be understood that this and other arrangements described herein are set forth only as examples. Other arrangements and elements (e.g., machines, interfaces, functions, orders, groupings of functions, etc.) may be used in addition to or instead of those shown, and some elements may be omitted altogether. Functional entities may be implemented as discrete or distributed components or in conjunction with other components, and in any suitable combination and location. Furthermore, persons of ordinary skill in the art will understand that any system that performs the operations of the data center server 100 is within the scope and spirit of embodiments of the present disclosure.

Data center server 100 includes a chassis 102, a GPU accelerator array 104 that includes a plurality of GPUs (e.g., 104A, 104B, and 104N), CPUs 106A and 106B, a power supply system, and a power distribution architecture for supplying power from the power supply system to GPUs of the multi-GPU accelerator array. By integrating a multi-GPU accelerator array 104 alongside traditional CPUs 106A and 106B, computationally intensive tasks can be offloaded from traditional CPUs and accelerated by leveraging the parallel processing capabilities of GPUs. Data center server 100 can achieve higher throughput and lower latency for various data-heavy operations and can perform a variety of computationally intense tasks for which GPU-acceleration is essential, e.g., artificial intelligence (AI) model training and inference, high-performance computing (HPC), and virtualization.

In one or more embodiments, data center server 100 is a modular data center server that can be combined with other modular data center servers to form a computing cluster. Modular server architectures simplify deployment and scalability by allowing rapid customization based on workload requirements, making them suitable for diverse environments including enterprise data centers, hyperscale deployments, and edge computing setups.

FIG. 1B is a top view of data center server 100. It should be understood that this and other arrangements described herein are set forth only as examples. Other arrangements and elements (e.g., machines, interfaces, functions, orders, groupings of functions, etc.) may be used in addition to or instead of those shown, and some elements may be omitted altogether. Functional entities may be implemented as discrete or distributed components or in conjunction with other components, and in any suitable combination and location. Furthermore, persons of ordinary skill in the art will understand that any system that performs the operations of the data center server 100 is within the scope and spirit of embodiments of the present disclosure.

FIG. 1B is a top view of data center server 100 in which a number of components have been omitted (e.g., only two GPUs 104A and 104B of multi-GPU accelerator array 104 are shown) to reveal certain components of a power supply and distribution architecture. The power supply and distribution architecture of data center server 100 includes a mid-chassis PDB 108 having a power converter 110 and a plurality of GPU power connectors 112. In one or more embodiments, the mid-chassis PDB 108 further includes a GPU interconnect board power connector configured to provide power directly to a GPU interconnect board at the operating voltage. In at least one embodiment, the power supply system includes one or more common redundant power supplies (CRPSs) 114 configured to supply power at the supply voltage. In at least one embodiment, the power supply system further includes one or more power supply PDBs, which are directly connected to the one or more CRPSs and configured to combine the power output of the one or more CRPSs. In at least one embodiment, the power supply system includes one or more AC connectors 116 configured to receive power supplied by one or more external power distribution units (PDUs). The power distribution system includes one or more busbars 118 and/or one or more transmission lines configured to transmit power from the power supply PDBs to the mid-chassis PDB at the supply voltage. In at least one embodiment, the one or more busbars are configured to transmit the combined power output of the one or more CRPSs to the mid-chassis PDB.

Power converter 110 is configured to convert a supply voltage supplied by one or more power supply units (PSUs) (e.g., the one or more CRPSs 114) to an operating voltage of the GPUs of the GPU accelerator array 104. In one or more embodiments, the supply voltage is 54V and the operating voltage is 12V. In one or more embodiments, the supply voltage is 48V and the operating voltage is 12V. In one or more embodiments, the power converter 110 includes one or more dual-regulated hybrid switched capacitor (DR-HSC) power converters. A DR-HSC power converter is an advanced DC-DC converter that combines switched-capacitor and magnetic-inductor-based designs to achieve high efficiency, power density, and precise voltage regulation. In one or more embodiments, the DR-HSC employs a two-stage topology, integrating flying capacitors and a multi-tapped autotransformer (MTA) to enable efficient energy transfer with reduced losses, e.g., through zero-voltage switching (ZVS).

In one or more embodiments, one or more (e.g., each) of the GPU power connectors 112 are configured to directly connect to a GPU of GPU accelerator array 104, e.g., by mating with a power input interface of the GPU, e.g., a power input interface on a printed circuit board (PCB) of the GPU. In one or more embodiments, one or more (e.g., each) of GPU power connectors 112 is a blade power connector including a conductive metal blade configured to output power directly to a GPU of GPU accelerator array 104 by mating with a corresponding power input of the GPU. In one or more embodiments, one or more (e.g., each) of GPU power connectors 112 is a pin power connector. In one or more embodiments, one or more (e.g., each) of GPU power connectors 112 is a PCI Express (PCIe) 5.0 CEM (Card Electromechanical) (“CEM5”) 16-pin power connector designed to support high-power GPUs and including 12 pins for power transmission and up to four additional pins for signaling, allowing communication of the maximum power capacity available to the GPU. In one or more embodiments, one or more (e.g., each) of GPU power connectors 112 is a slot power connector. In one or more embodiments, one or more (e.g., each) of the GPU power connectors 112 are directly connected to the power converter 110 and configured to directly connect to a GPU of GPU accelerator array 104, e.g., via a power input interface of the GPU.

In one or more embodiments, the one or more CRPSs 114 supply power at a supply voltage. In one or more embodiments, the supply voltage is 54V. In one or more embodiments, the supply voltage is 48V. CRPSs, such as the one or more CRPSs 114, are capable of providing uninterrupted operation and high availability, even in the event of a hardware failure or maintenance. By utilizing a PSU with multiple CRPSs, redundancy models, e.g., N+1 (where an additional power supply unit is included as a backup to support a load if a primary unit fails) or 2N (where an entire power supply system is mirrored for complete fault tolerance), can be implemented. Such redundancy is particularly important for supporting critical applications in industries like cloud computing, AI, and enterprise IT, where even brief downtime can result in significant financial and/or operational losses. In one or more embodiments, the one or more CRPSs 114 receive power, e.g., from one or more external power distribution units (PDUs), via the one or more AC connectors 116. In one or more embodiments, the one or more AC connectors 116 provide power at an AC distribution voltage (e.g., 208V AC, 230V AC, 240V AC, etc.) to the one or more CRPSs 114 from, e.g., an uninterruptable power supply (UPS), backup generators, and/or redundant power distribution paths.

In one or more embodiments, the one or more busbars 118 transmit power from the one or more CRPSs 114 to the mid-chassis PDB 108 at the supply voltage. In one or more embodiments, the one or more busbars 118 transmit power at a supply voltage of 54V or at a supply voltage of 48V.

FIG. 1C is a perspective view of certain components of a power supply and distribution architecture of data center server 100, in accordance with one or more embodiments. It should be understood that this and other arrangements described herein are set forth only as examples. Other arrangements and elements (e.g., machines, interfaces, functions, orders, groupings of functions, etc.) may be used in addition to or instead of those shown, and some elements may be omitted altogether. Functional entities may be implemented as discrete or distributed components or in conjunction with other components, and in any suitable combination and location. Furthermore, persons of ordinary skill in the art will understand that any system that performs the operations of the data center server 100 is within the scope and spirit of embodiments of the present disclosure.

FIG. 1C illustrates certain components of a power supply and distribution architecture, including the mid-chassis PDB 108 having the power converter 110 and the plurality of GPU power connectors 112 as described above in the context of FIG. 1B. The mid-chassis PDB 108 is connected by busbars 118 to one or more power supply units (PSUs) (e.g., the one or more CRPSs 114), which are not depicted in FIG. 1C. Due to the positioning of power converter 110 and the GPU power connectors 112 on mid-chassis PDB 108, busbars 118 are able to transport power at a relatively higher supply voltage (e.g., 54V or 48V) rather than a relatively lower GPU operating voltage (e.g., 12V).

As a result of the configuration of the power supply and distribution architecture, relatively smaller and lighter busbars can be used without causing excess transmission losses or heat generation and without negatively impacting the longevity and reliability of the power distribution architecture. Experimentation and reliability testing has demonstrated that certain busbar cross-sectional area-to-transmitted total board power (TBP) ratios achieve a superior balance of transmission performance and reliability. In one or more embodiments, busbars 118 have a cross-sectional area-to-transmitted total board power (TBP) ratio less than 10 mm²/kW, preferably less than 8 mm²/kW, preferably in a range of 4.5 mm²/kW to 8 mm²/kW, demonstrated a superior balance of transmission performance and reliability.

In one or more embodiments, data center server 100 includes a GPU accelerator array 104 with an aggregated TBP of 24.0 kW, and a single busbar 118 with a cross sectional area of 125 mm² (and a cross-sectional area-to-transmitted TBP power ratio of 5.2 mm²/kW) transmits power to the mid-chassis PDB 108 at a 54V supply voltage.

In one or more embodiments, data center server 100 includes a GPU accelerator array 104 with an aggregated TBP of 11.0 kW, and a single busbar 118 with a cross sectional area of 72.5 mm² (and a cross-sectional area-to-transmitted TBP power ratio of 6.8 mm²/kW) transmits power to the mid-chassis PDB 108 at a 54V supply voltage.

In one or more embodiments, data center server 100 includes a GPU accelerator array 104 with an aggregated TBP of 16.2 kW, and a single busbar 118 with a cross sectional area of 72.5 mm² (and a cross-sectional area-to-transmitted TBP power ratio of 4.6 mm²/kW) transmits power to the mid-chassis PDB 108 at a 54V supply voltage.

In one or more embodiments, data center server 100 includes a GPU accelerator array 104 with an aggregated TBP of 18.8 kW, and two busbars 118 collectively having a cross sectional area of 145 mm² (and a cross-sectional area-to-transmitted TBP power ratio of 8.0 mm²/kW) transmit power to the mid-chassis PDB 108 at a 54V supply voltage.

In one or more embodiments, data center server 100 includes a GPU accelerator array 104 with an aggregated TBP of 22.1 kW, and two busbars 118 collectively having a cross sectional area of 145 mm² (and a cross-sectional area-to-transmitted TBP power ratio of 6.8 mm²/kW) transmit power to the mid-chassis PDB 108 at a 54V supply voltage.

In one or more embodiments, data center server 100 includes a GPU accelerator array 104 with an aggregated TBP of 23.7 kW, and two busbars 118 collectively having a cross sectional area of 145 mm² (and a cross-sectional area-to-transmitted TBP power ratio of 6.3 mm²/kW) transmit power to the mid-chassis PDB 108 at a 54V supply voltage.

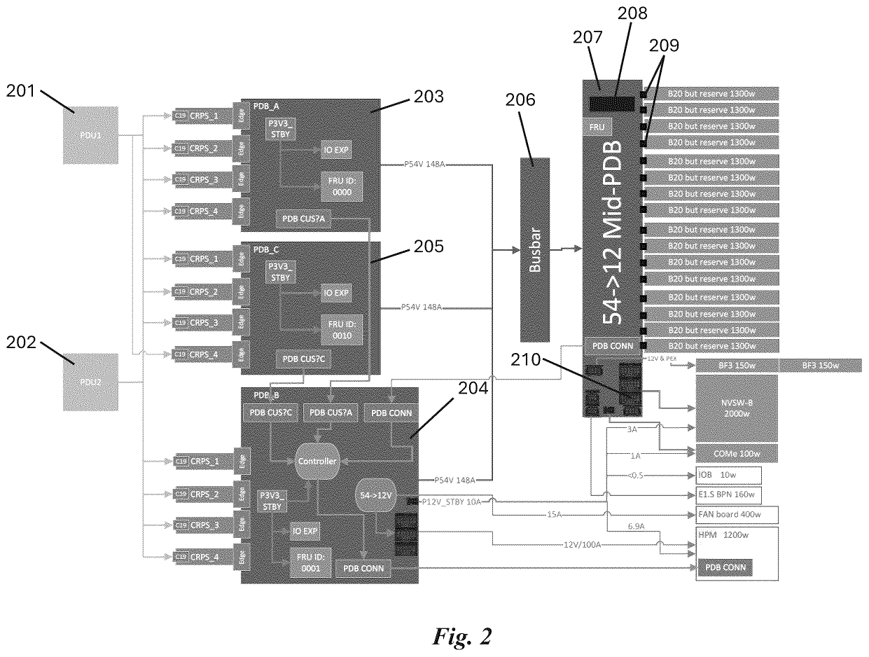

FIG. 2 is a block diagram of a power supply and distribution architecture 200 according to one or more embodiments. It should be understood that this and other arrangements described herein are set forth only as examples. Other arrangements and elements (e.g., machines, interfaces, functions, orders, groupings of functions, etc.) may be used in addition to or instead of those shown, and some elements may be omitted altogether. Functional entities may be implemented as discrete or distributed components or in conjunction with other components, and in any suitable combination and location. Furthermore, persons of ordinary skill in the art will understand that any system that performs the operations of the power supply and distribution architecture 200 is within the scope and spirit of embodiments of the present disclosure.

Power supply and distribution architecture 200 includes two power distribution units (PDU1 201 and PDU2 202) and three power supply unit (PSU) power distribution boards (PDB_A 203, PDB_B 204, and PDB_C 205)—each connected to four CRPSs (i.e., CRPS_1, CRPS_2, CRPS_3, and CRPS_4). In one or more embodiments, the CRPSs to which PDBs 203, 204, and 205 are connected are the one or more CRPSs 114 of FIGS. 1B and 1C. Power supply and distribution architecture 200 further includes one or more busbars 206 that transmit power from PDB_A 203 and PDB_C 205 to a mid-chassis PDB 207. Mid-chassis PDB 207 includes a power converter 208, a plurality of GPU power connectors 209, and a GPU interconnect board power connector 210 configured to provide power directly to a GPU interconnect board at the operating voltage. In one or more embodiments, the one or more busbars 206, the mid-chassis PDB 207, and the plurality of GPU power connectors 209 are, respectively, the busbars 118, the mid-chassis PDB 108, and the GPU power connectors 112 of FIGS. 1B and 1C.

By providing power converter 210 at mid-chassis PDB 207 along with the plurality of GPU power connectors 209 and the GPU interconnect board power connector 210, power can be transported by the one or more busbars 206 at a relatively higher supply voltage rather than a relatively lower operating voltage, enabling relatively lightweight construction of the one or more busbars 206 without excess transmission losses or heat generation and without negatively impacting the longevity and reliability of the power supply and distribution architecture 200.

More illustrative information will now be set forth regarding various optional architectures and features related to one or more of the aforementioned embodiments, per the desires of the user. It should be strongly noted that the following information is set forth for illustrative purposes and should not be construed as limiting in any manner. Any of the following features may be optionally incorporated with or without the exclusion of other features described.

### Parallel Processing Architecture

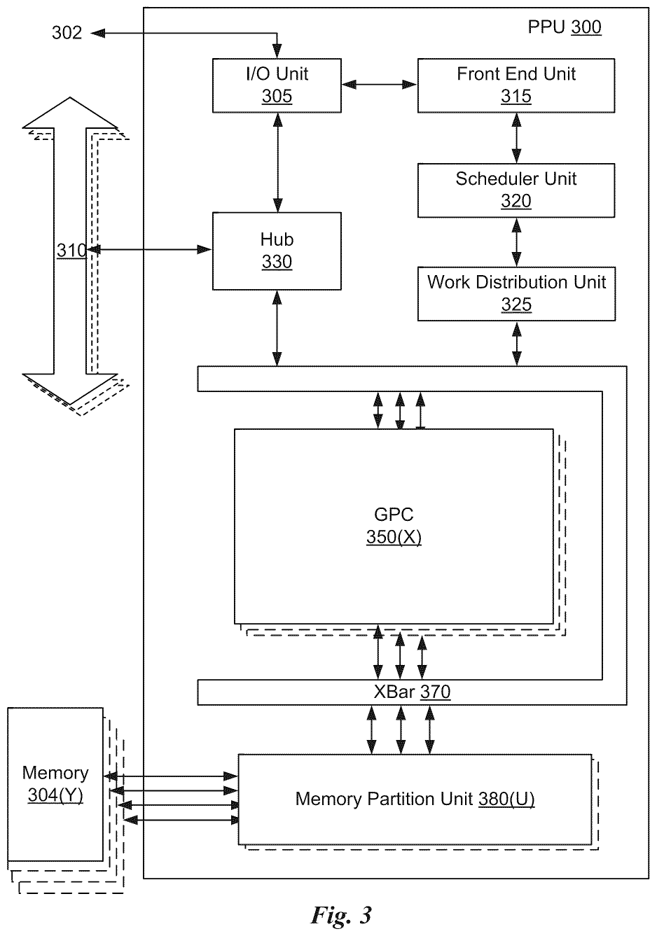

FIG. 3 illustrates a parallel processing unit (PPU) 300, in accordance with an embodiment. In an embodiment, the PPU 300 is a multi-threaded processor that is implemented on one or more integrated circuit devices. The PPU 300 is a latency hiding architecture designed to process many threads in parallel. A thread (e.g., a thread of execution) is an instantiation of a set of instructions configured to be executed by the PPU 300. In an embodiment, the PPU 300 is a graphics processing unit (GPU) configured to implement a graphics rendering pipeline for processing three-dimensional (3D) graphics data in order to generate two-dimensional (2D) image data for display on a display device such as a liquid crystal display (LCD) device. In other embodiments, the PPU 300 may be utilized for performing general-purpose computations. While one exemplary parallel processor is provided herein for illustrative purposes, it should be strongly noted that such processor is set forth for illustrative purposes only, and that any processor may be employed to supplement and/or substitute for the same.

One or more PPUs 300 may be configured to accelerate thousands of High Performance Computing (HPC), data center, and machine learning applications. The PPU 300 may be configured to accelerate numerous deep learning systems and applications including autonomous vehicle platforms, deep learning, high-accuracy speech, image, and text recognition systems, intelligent video analytics, molecular simulations, drug discovery, disease diagnosis, weather forecasting, big data analytics, astronomy, molecular dynamics simulation, financial modeling, robotics, factory automation, real-time language translation, online search optimizations, and personalized user recommendations, and the like.

As shown in FIG. 3, the PPU 300 includes an Input/Output (I/O) unit 305, a front end unit 315, a scheduler unit 320, a work distribution unit 325, a hub 330, a crossbar (Xbar) 370, one or more general processing clusters (GPCs) 350, and one or more partition units 380. The PPU 300 may be connected to a host processor or other PPUs 300 via one or more high-speed NVLink 310 interconnect. The PPU 300 may be connected to a host processor or other peripheral devices via an interconnect 302. The PPU 300 may also be connected to a local memory comprising a number of memory devices 304. In an embodiment, the local memory may comprise a number of dynamic random access memory (DRAM) devices. The DRAM devices may be configured as a high-bandwidth memory (HBM) subsystem, with multiple DRAM dies stacked within each device.

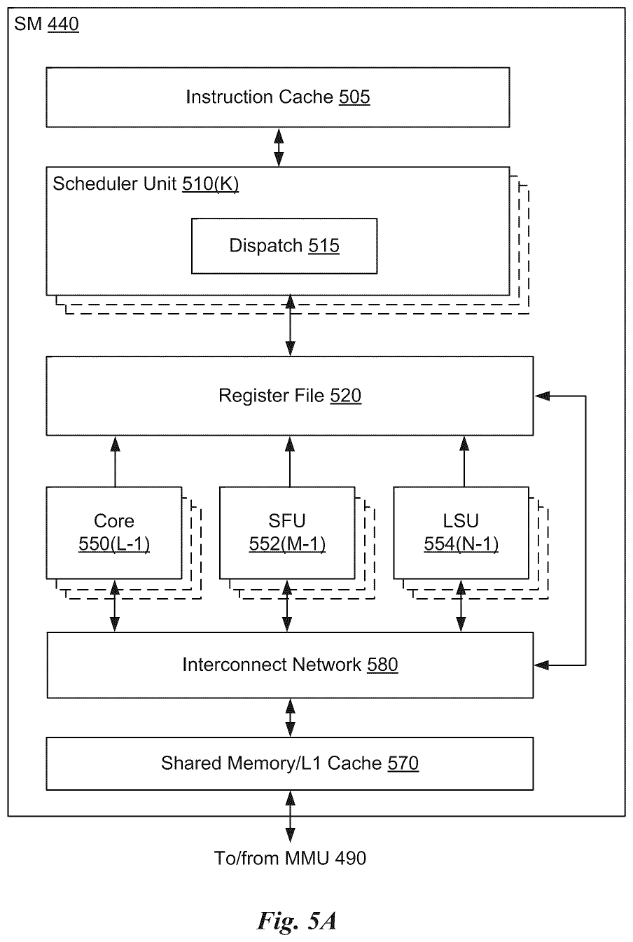

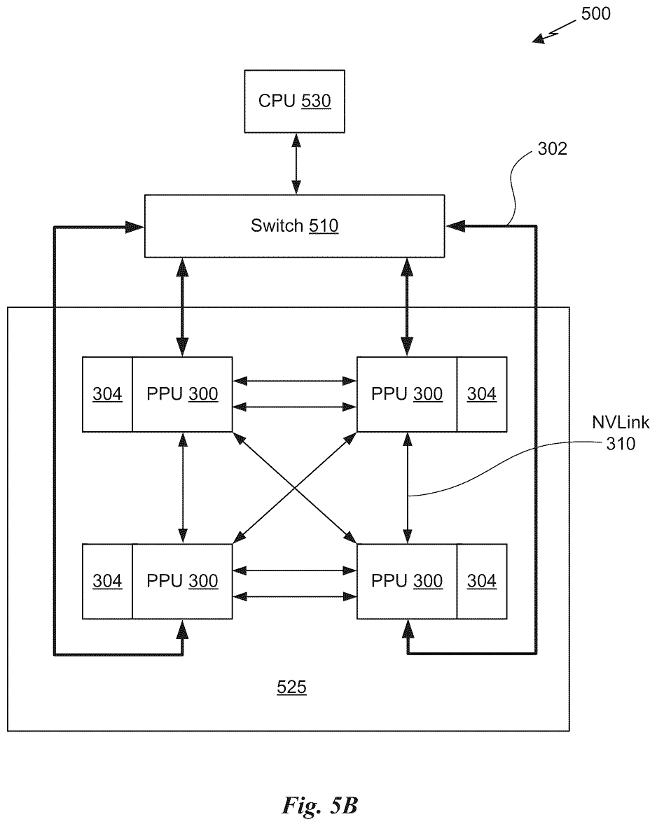

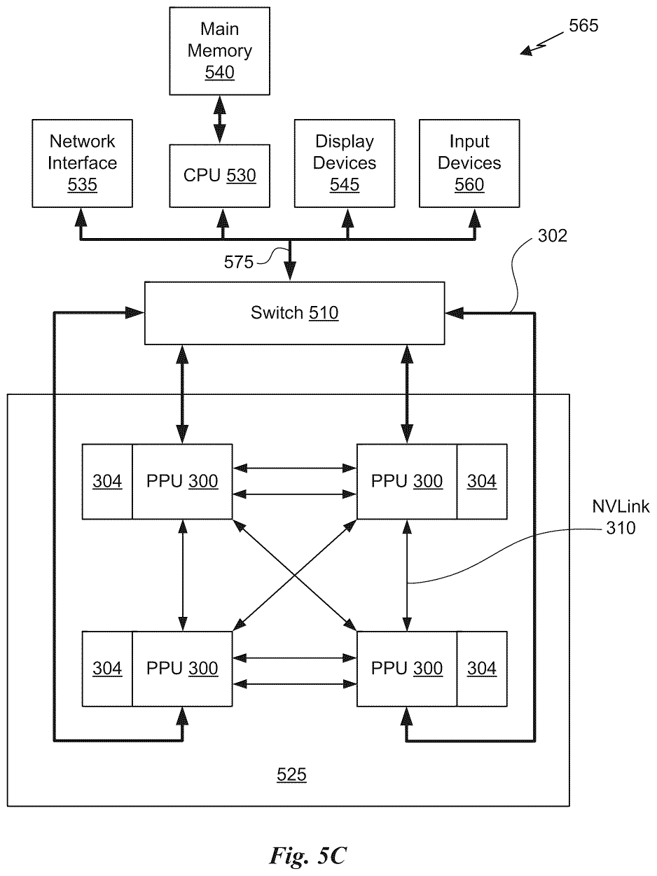

The NVLink 310 interconnect enables systems to scale and include one or more PPUs 300 combined with one or more CPUs, supports cache coherence between the PPUs 300 and CPUs, and CPU mastering. Data and/or commands may be transmitted by the NVLink 310 through the hub 330 to/from other units of the PPU 300 such as one or more copy engines, a video encoder, a video decoder, a power management unit, etc. (not explicitly shown). The NVLink 310 is described in more detail in conjunction with FIG. 5B.

The I/O unit 305 is configured to transmit and receive communications (e.g., commands, data, etc.) from a host processor (not shown) over the interconnect 302. The I/O unit 305 may communicate with the host processor directly via the interconnect 302 or through one or more intermediate devices such as a memory bridge. In an embodiment, the I/O unit 305 may communicate with one or more other processors, such as one or more the PPUs 300 via the interconnect 302. In an embodiment, the I/O unit 305 implements a Peripheral Component Interconnect Express (PCIe) interface for communications over a PCIe bus and the interconnect 302 is a PCIe bus. In alternative embodiments, the I/O unit 305 may implement other types of well-known interfaces for communicating with external devices.

The I/O unit 305 decodes packets received via the interconnect 302. In an embodiment, the packets represent commands configured to cause the PPU 300 to perform various operations. The I/O unit 305 transmits the decoded commands to various other units of the PPU 300 as the commands may specify. For example, some commands may be transmitted to the front end unit 315. Other commands may be transmitted to the hub 330 or other units of the PPU 300 such as one or more copy engines, a video encoder, a video decoder, a power management unit, etc. (not explicitly shown). In other words, the I/O unit 305 is configured to route communications between and among the various logical units of the PPU 300.

In an embodiment, a program executed by the host processor encodes a command stream in a buffer that provides workloads to the PPU 300 for processing. A workload may comprise several instructions and data to be processed by those instructions. The buffer is a region in a memory that is accessible (e.g., read/write) by both the host processor and the PPU 300. For example, the I/O unit 305 may be configured to access the buffer in a system memory connected to the interconnect 302 via memory requests transmitted over the interconnect 302. In an embodiment, the host processor writes the command stream to the buffer and then transmits a pointer to the start of the command stream to the PPU 300. The front end unit 315 receives pointers to one or more command streams. The front end unit 315 manages the one or more streams, reading commands from the streams and forwarding commands to the various units of the PPU 300.

The front end unit 315 is coupled to a scheduler unit 320 that configures the various GPCs 350 to process tasks defined by the one or more streams. The scheduler unit 320 is configured to track state information related to the various tasks managed by the scheduler unit 320. The state may indicate which GPC 350 a task is assigned to, whether the task is active or inactive, a priority level associated with the task, and so forth. The scheduler unit 320 manages the execution of a plurality of tasks on the one or more GPCs 350.

The scheduler unit 320 is coupled to a work distribution unit 325 that is configured to dispatch tasks for execution on the GPCs 350. The work distribution unit 325 may track a number of scheduled tasks received from the scheduler unit 320. In an embodiment, the work distribution unit 325 manages a pending task pool and an active task pool for each of the GPCs 350. The pending task pool may comprise a number of slots (e.g., 32 slots) that contain tasks assigned to be processed by a particular GPC 350. The active task pool may comprise a number of slots (e.g., 4 slots) for tasks that are actively being processed by the GPCs 350. As a GPC 350 finishes the execution of a task, that task is evicted from the active task pool for the GPC 350 and one of the other tasks from the pending task pool is selected and scheduled for execution on the GPC 350. If an active task has been idle on the GPC 350, such as while waiting for a data dependency to be resolved, then the active task may be evicted from the GPC 350 and returned to the pending task pool while another task in the pending task pool is selected and scheduled for execution on the GPC 350.

The work distribution unit 325 communicates with the one or more GPCs 350 via XBar 370. The XBar 370 is an interconnect network that couples many of the units of the PPU 300 to other units of the PPU 300. For example, the XBar 370 may be configured to couple the work distribution unit 325 to a particular GPC 350. Although not shown explicitly, one or more other units of the PPU 300 may also be connected to the XBar 370 via the hub 330.

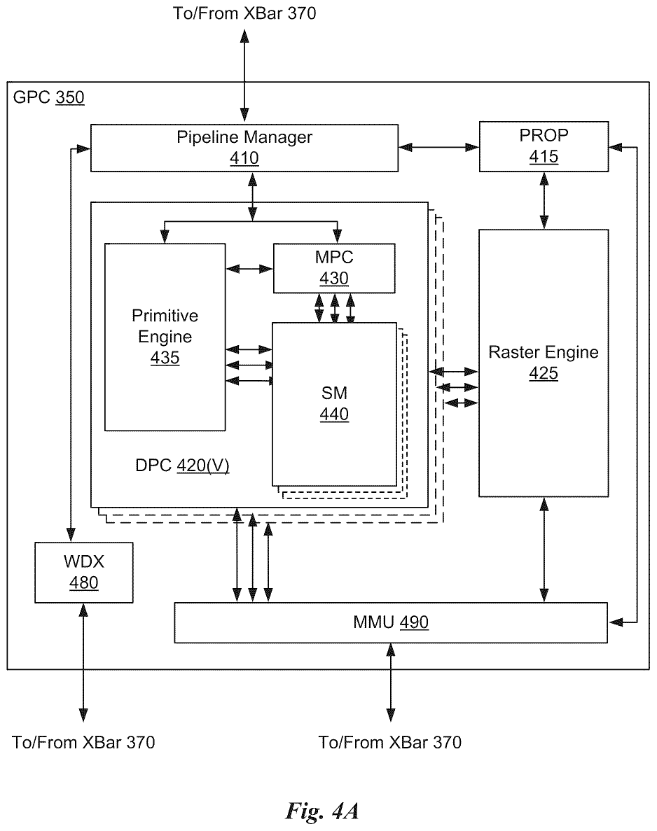

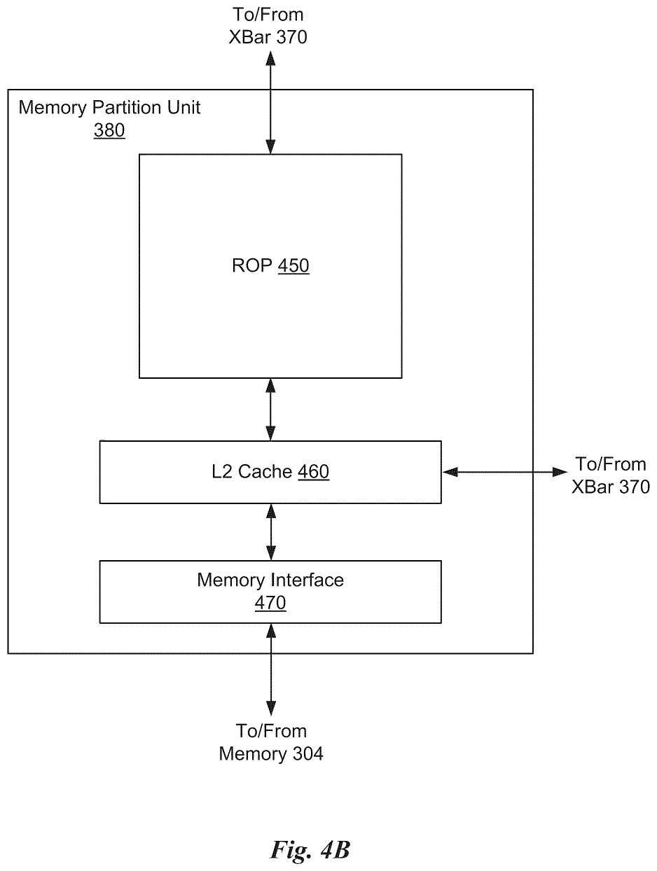

The tasks are managed by the scheduler unit 320 and dispatched to a GPC 350 by the work distribution unit 325. The GPC 350 is configured to process the task and generate results. The results may be consumed by other tasks within the GPC 350, routed to a different GPC 350 via the XBar 370, or stored in the memory 304. The results can be written to the memory 304 via the partition units 380, which implement a memory interface for reading and writing data to/from the memory 304. The results can be transmitted to another PPU 304 or CPU via the NVLink 310. In an embodiment, the PPU 300 includes a number U of partition units 380 that is equal to the number of separate and distinct memory devices 304 coupled to the PPU 300. A partition unit 380 will be described in more detail below in conjunction with FIG. 4B.

In an embodiment, a host processor executes a driver kernel that implements an application programming interface (API) that enables one or more applications executing on the host processor to schedule operations for execution on the PPU 300. In an embodiment, multiple compute applications are simultaneously executed by the PPU 300 and the PPU 300 provides isolation, quality of service (QoS), and independent address spaces for the multiple compute applications. An application may generate instructions (e.g., API calls) that cause the driver kernel to generate one or more tasks for execution by the PPU 300. The driver kernel outputs tasks to one or more streams being processed by the PPU 300. Each task may comprise one or more groups of related threads, referred to herein as a warp. In an embodiment, a warp comprises 32 related threads that may be executed in parallel. Cooperating threads may refer to a plurality of threads including instructions to perform the task and that may exchange data through shared memory. Threads and cooperating threads are described in more detail in conjunction with FIG. 5A.

FIG. 4A illustrates a GPC 350 of the PPU 300 of FIG. 3, in accordance with an embodiment. As shown in FIG. 4A, each GPC 350 includes a number of hardware units for processing tasks. In an embodiment, each GPC 350 includes a pipeline manager 410, a pre-raster operations unit (PROP) 415, a raster engine 425, a work distribution crossbar (WDX) 480, a memory management unit (MMU) 490, and one or more Data Processing Clusters (DPCs) 420. It will be appreciated that the GPC 350 of FIG. 4A may include other hardware units in lieu of or in addition to the units shown in FIG. 4A.

In an embodiment, the operation of the GPC 350 is controlled by the pipeline manager 410. The pipeline manager 410 manages the configuration of the one or more DPCs 420 for processing tasks allocated to the GPC 350. In an embodiment, the pipeline manager 410 may configure at least one of the one or more DPCs 420 to implement at least a portion of a graphics rendering pipeline. For example, a DPC 420 may be configured to execute a vertex shader program on the programmable streaming multiprocessor (SM) 440. The pipeline manager 410 may also be configured to route packets received from the work distribution unit 325 to the appropriate logical units within the GPC 350. For example, some packets may be routed to fixed function hardware units in the PROP 415 and/or raster engine 425 while other packets may be routed to the DPCs 420 for processing by the primitive engine 435 or the SM 440. In an embodiment, the pipeline manager 410 may configure at least one of the one or more DPCs 420 to implement a neural network model and/or a computing pipeline.

The PROP unit 415 is configured to route data generated by the raster engine 425 and the DPCs 420 to a Raster Operations (ROP) unit, described in more detail in conjunction with FIG. 4B. The PROP unit 415 may also be configured to perform optimizations for color blending, organize pixel data, perform address translations, and the like.

The raster engine 425 includes a number of fixed function hardware units configured to perform various raster operations. In an embodiment, the raster engine 425 includes a setup engine, a coarse raster engine, a culling engine, a clipping engine, a fine raster engine, and a tile coalescing engine. The setup engine receives transformed vertices and generates plane equations associated with the geometric primitive defined by the vertices. The plane equations are transmitted to the coarse raster engine to generate coverage information (e.g., an x,y coverage mask for a tile) for the primitive. The output of the coarse raster engine is transmitted to the culling engine where fragments associated with the primitive that fail a z-test are culled, and transmitted to a clipping engine where fragments lying outside a viewing frustum are clipped. Those fragments that survive clipping and culling may be passed to the fine raster engine to generate attributes for the pixel fragments based on the plane equations generated by the setup engine. The output of the raster engine 425 comprises fragments to be processed, for example, by a fragment shader implemented within a DPC 420.

Each DPC 420 included in the GPC 350 includes an M-Pipe Controller (MPC) 430, a primitive engine 435, and one or more SMs 440. The MPC 430 controls the operation of the DPC 420, routing packets received from the pipeline manager 410 to the appropriate units in the DPC 420. For example, packets associated with a vertex may be routed to the primitive engine 435, which is configured to fetch vertex attributes associated with the vertex from the memory 304. In contrast, packets associated with a shader program may be transmitted to the SM 440.

The SM 440 comprises a programmable streaming processor that is configured to process tasks represented by a number of threads. Each SM 440 is multi-threaded and configured to execute a plurality of threads (e.g., 32 threads) from a particular group of threads concurrently. In an embodiment, the SM 440 implements a SIMD (Single-Instruction, Multiple-Data) architecture where each thread in a group of threads (e.g., a warp) is configured to process a different set of data based on the same set of instructions. All threads in the group of threads execute the same instructions. In another embodiment, the SM 440 implements a SIMT (Single-Instruction, Multiple Thread) architecture where each thread in a group of threads is configured to process a different set of data based on the same set of instructions, but where individual threads in the group of threads are allowed to diverge during execution. In an embodiment, a program counter, call stack, and execution state is maintained for each warp, enabling concurrency between warps and serial execution within warps when threads within the warp diverge. In another embodiment, a program counter, call stack, and execution state is maintained for each individual thread, enabling equal concurrency between all threads, within and between warps. When execution state is maintained for each individual thread, threads executing the same instructions may be converged and executed in parallel for maximum efficiency. The SM 440 will be described in more detail below in conjunction with FIG. 5A.

The MMU 490 provides an interface between the GPC 350 and the partition unit 380. The MMU 490 may provide translation of virtual addresses into physical addresses, memory protection, and arbitration of memory requests. In an embodiment, the MMU 490 provides one or more translation lookaside buffers (TLBs) for performing translation of virtual addresses into physical addresses in the memory 304.

FIG. 4B illustrates a memory partition unit 380 of the PPU 300 of FIG. 3, in accordance with an embodiment. As shown in FIG. 4B, the memory partition unit 380 includes a Raster Operations (ROP) unit 450, a level two (L2) cache 460, and a memory interface 470. The memory interface 470 is coupled to the memory 304. Memory interface 470 may implement 32, 64, 128, 1024-bit data buses, or the like, for high-speed data transfer. In an embodiment, the PPU 300 incorporates U memory interfaces 470, one memory interface 470 per pair of partition units 380, where each pair of partition units 380 is connected to a corresponding memory device 304. For example, PPU 300 may be connected to up to Y memory devices 304, such as high bandwidth memory stacks or graphics double-data-rate, version 5, synchronous dynamic random access memory, or other types of persistent storage.

In an embodiment, the memory interface 470 implements an HBM2 memory interface and Y equals half U. In an embodiment, the HBM2 memory stacks are located on the same physical package as the PPU 300, providing substantial power and area savings compared with conventionalGDDR5 SDRAM systems. In an embodiment, each HBM2 stack includes four memory dies and Y equals 4, with HBM2 stack including two 128-bit channels per die for a total of 8 channels and a data bus width of 1024 bits.

In an embodiment, the memory 304 supports Single-Error Correcting Double-Error Detecting (SECDED) Error Correction Code (ECC) to protect data. ECC provides higher reliability for compute applications that are sensitive to data corruption. Reliability is especially important in large-scale cluster computing environments where PPUs 300 process very large datasets and/or run applications for extended periods.

In an embodiment, the PPU 300 implements a multi-level memory hierarchy. In an embodiment, the memory partition unit 380 supports a unified memory to provide a single unified virtual address space for CPU and PPU 300 memory, enabling data sharing between virtual memory systems. In an embodiment the frequency of accesses by a PPU 300 to memory located on other processors is traced to ensure that memory pages are moved to the physical memory of the PPU 300 that is accessing the pages more frequently. In an embodiment, the NVLink 310 supports address translation services allowing the PPU 300 to directly access a CPU's page tables and providing full access to CPU memory by the PPU 300.

In an embodiment, copy engines transfer data between multiple PPUs 300 or between PPUs 300 and CPUs. The copy engines can generate page faults for addresses that are not mapped into the page tables. The memory partition unit 380 can then service the page faults, mapping the addresses into the page table, after which the copy engine can perform the transfer. In a conventional system, memory is pinned (e.g., non-pageable) for multiple copy engine operations between multiple processors, substantially reducing the available memory. With hardware page faulting, addresses can be passed to the copy engines without worrying if the memory pages are resident, and the copy process is transparent.

Data from the memory 304 or other system memory may be fetched by the memory partition unit 380 and stored in the L2 cache 460, which is located on-chip and is shared between the various GPCs 350. As shown, each memory partition unit 380 includes a portion of the L2 cache 460 associated with a corresponding memory device 304. Lower level caches may then be implemented in various units within the GPCs 350. For example, each of the SMs 440 may implement a level one (L1) cache. The L1 cache is private memory that is dedicated to a particular SM 440. Data from the L2 cache 460 may be fetched and stored in each of the L1 caches for processing in the functional units of the SMs 440. The L2 cache 460 is coupled to the memory interface 470 and the XBar 370.

The ROP unit 450 performs graphics raster operations related to pixel color, such as color compression, pixel blending, and the like. The ROP unit 450 also implements depth testing in conjunction with the raster engine 425, receiving a depth for a sample location associated with a pixel fragment from the culling engine of the raster engine 425. The depth is tested against a corresponding depth in a depth buffer for a sample location associated with the fragment. If the fragment passes the depth test for the sample location, then the ROP unit 450 updates the depth buffer and transmits a result of the depth test to the raster engine 425. It will be appreciated that the number of partition units 380 may be different than the number of GPCs 350 and, therefore, each ROP unit 450 may be coupled to each of the GPCs 350. The ROP unit 450 tracks packets received from the different GPCs 350 and determines which GPC 350 that a result generated by the ROP unit 450 is routed to through the Xbar 370. Although the ROP unit 450 is included within the memory partition unit 380 in FIG. 4B, in other embodiment, the ROP unit 450 may be outside of the memory partition unit 380. For example, the ROP unit 450 may reside in the GPC 350 or another unit.

FIG. 5A illustrates the streaming multi-processor 440 of FIG. 4A, in accordance with an embodiment. As shown in FIG. 5A, the SM 440 includes an instruction cache 505, one or more scheduler units 510, a register file 520, one or more processing cores 550, one or more special function units (SFUs) 552, one or more load/store units (LSUs) 554, an interconnect network 580, a shared memory/L1 cache 570.

As described above, the work distribution unit 325 dispatches tasks for execution on the GPCs 350 of the PPU 300. The tasks are allocated to a particular DPC 420 within a GPC 350 and, if the task is associated with a shader program, the task may be allocated to an SM 440. The scheduler unit 510 receives the tasks from the work distribution unit 325 and manages instruction scheduling for one or more thread blocks assigned to the SM 440. The scheduler unit 510 schedules thread blocks for execution as warps of parallel threads, where each thread block is allocated at least one warp. In an embodiment, each warp executes 32 threads. The scheduler unit 510 may manage a plurality of different thread blocks, allocating the warps to the different thread blocks and then dispatching instructions from the plurality of different cooperative groups to the various functional units (e.g., cores 550, SFUs 552, and LSUs 554) during each clock cycle.

Cooperative Groups is a programming model for organizing groups of communicating threads that allows developers to express the granularity at which threads are communicating, enabling the expression of richer, more efficient parallel decompositions. Cooperative launch APIs support synchronization amongst thread blocks for the execution of parallel algorithms. Conventional programming models provide a single, simple construct for synchronizing cooperating threads: a barrier across all threads of a thread block (e.g., the syncthreads( ) function). However, programmers would often like to define groups of threads at smaller than thread block granularities and synchronize within the defined groups to enable greater performance, design flexibility, and software reuse in the form of collective group-wide function interfaces.

Cooperative Groups enables programmers to define groups of threads explicitly at sub-block (e.g., as small as a single thread) and multi-block granularities, and to perform collective operations such as synchronization on the threads in a cooperative group. The programming model supports clean composition across software boundaries, so that libraries and utility functions can synchronize safely within their local context without having to make assumptions about convergence. Cooperative Groups primitives enable new patterns of cooperative parallelism, including producer-consumer parallelism, opportunistic parallelism, and global synchronization across an entire grid of thread blocks.

A dispatch unit 515 is configured to transmit instructions to one or more of the functional units. In the embodiment, the scheduler unit 510 includes two dispatch units 515 that enable two different instructions from the same warp to be dispatched during each clock cycle. In alternative embodiments, each scheduler unit 510 may include a single dispatch unit 515 or additional dispatch units 515.

Each SM 440 includes a register file 520 that provides a set of registers for the functional units of the SM 440. In an embodiment, the register file 520 is divided between each of the functional units such that each functional unit is allocated a dedicated portion of the register file 520. In another embodiment, the register file 520 is divided between the different warps being executed by the SM 440. The register file 520 provides temporary storage for operands connected to the data paths of the functional units.

Each SM 440 comprises Z processing cores 550. In an embodiment, the SM 440 includes a large number (e.g., 128, etc.) of distinct processing cores 550. Each core 550 may include a fully-pipelined, single-precision, double-precision, and/or mixed precision processing unit that includes a floating point arithmetic logic unit and an integer arithmetic logic unit. In an embodiment, the floating point arithmetic logic units implement the IEEE 754-2008 standard for floating point arithmetic. In an embodiment, the cores 550 include 64 single-precision (32-bit) floating point cores, 64 integer cores, 32 double-precision (64-bit) floating point cores, and 8 tensor cores.

Tensor cores configured to perform matrix operations, and, in an embodiment, one or more tensor cores are included in the cores 550. In particular, the tensor cores are configured to perform deep learning matrix arithmetic, such as convolution operations for neural network training and inferencing. In an embodiment, each tensor core operates on a 4×4 matrix and performs a matrix multiply and accumulate operation D=A×B+C, where A, B, C, and D are 4×4 matrices.

In an embodiment, the matrix multiply inputs A and B are 16-bit floating point matrices, while the accumulation matrices C and D may be 16-bit floating point or 32-bit floating point matrices. Tensor Cores operate on 16-bit floating point input data with 32-bit floating point accumulation. The 16-bit floating point multiply requires 64 operations and results in a full precision product that is then accumulated using 32-bit floating point addition with the other intermediate products for a 4×4×4 matrix multiply. In practice, Tensor Cores are used to perform much larger two-dimensional or higher dimensional matrix operations, built up from these smaller elements. An API, such as CUDA 9 C++ API, exposes specialized matrix load, matrix multiply and accumulate, and matrix store operations to efficiently use Tensor Cores from a CUDA-C++ program. At the CUDA level, the warp-level interface assumes 16×16 size matrices spanning all 32 threads of the warp.

Each SM 440 also comprises M SFUs 552 that perform special functions (e.g., attribute evaluation, reciprocal square root, and the like). In an embodiment, the SFUs 552 may include a tree traversal unit configured to traverse a hierarchical tree data structure. In an embodiment, the SFUs 552 may include texture unit configured to perform texture map filtering operations. In an embodiment, the texture units are configured to load texture maps (e.g., a 2D array of texels) from the memory 304 and sample the texture maps to produce sampled texture values for use in shader programs executed by the SM 440. In an embodiment, the texture maps are stored in the shared memory/L1 cache 470. The texture units implement texture operations such as filtering operations using mip-maps (e.g., texture maps of varying levels of detail). In an embodiment, each SM 340 includes two texture units.

Each SM 440 also comprises N LSUs 554 that implement load and store operations between the shared memory/L1 cache 570 and the register file 520. Each SM 440 includes an interconnect network 580 that connects each of the functional units to the register file 520 and the LSU 554 to the register file 520, shared memory/L1 cache 570. In an embodiment, the interconnect network 580 is a crossbar that can be configured to connect any of the functional units to any of the registers in the register file 520 and connect the LSUs 554 to the register file and memory locations in shared memory/L1 cache 570.

The shared memory/L1 cache 570 is an array of on-chip memory that allows for data storage and communication between the SM 440 and the primitive engine 435 and between threads in the SM 440. In an embodiment, the shared memory/L1 cache 570 comprises 128 KB of storage capacity and is in the path from the SM 440 to the partition unit 380. The shared memory/L1 cache 570 can be used to cache reads and writes. One or more of the shared memory/L1 cache 570, L2 cache 460, and memory 304 are backing stores.

Combining data cache and shared memory functionality into a single memory block provides the best overall performance for both types of memory accesses. The capacity is usable as a cache by programs that do not use shared memory. For example, if shared memory is configured to use half of the capacity, texture and load/store operations can use the remaining capacity. Integration within the shared memory/L1 cache 570 enables the shared memory/L1 cache 570 to function as a high-throughput conduit for streaming data while simultaneously providing high-bandwidth and low-latency access to frequently reused data.

When configured for general purpose parallel computation, a simpler configuration can be used compared with graphics processing. Specifically, the fixed function graphics processing units shown in FIG. 3, are bypassed, creating a much simpler programming model. In the general purpose parallel computation configuration, the work distribution unit 325 assigns and distributes blocks of threads directly to the DPCs 420. The threads in a block execute the same program, using a unique thread ID in the calculation to ensure each thread generates unique results, using the SM 440 to execute the program and perform calculations, shared memory/L1 cache 570 to communicate between threads, and the LSU 554 to read and write global memory through the shared memory/L1 cache 570 and the memory partition unit 380. When configured for general purpose parallel computation, the SM 440 can also write commands that the scheduler unit 320 can use to launch new work on the DPCs 420.

The PPU 300 may be included in a desktop computer, a laptop computer, a tablet computer, servers, supercomputers, a smart-phone (e.g., a wireless, hand-held device), personal digital assistant (PDA), a digital camera, a vehicle, a head mounted display, a hand-held electronic device, and the like. In an embodiment, the PPU 300 is embodied on a single semiconductor substrate. In another embodiment, the PPU 300 is included in a system-on-a-chip (SoC) along with one or more other devices such as additional PPUs 300, the memory 304, a reduced instruction set computer (RISC) CPU, a memory management unit (MMU), a digital-to-analog converter (DAC), and the like.

In an embodiment, the PPU 300 may be included on a graphics card that includes one or more memory devices 304. The graphics card may be configured to interface with a PCIe slot on a motherboard of a desktop computer. In yet another embodiment, the PPU 300 may be an integrated graphics processing unit (iGPU) or parallel processor included in the chipset of the motherboard.

### Exemplary Computing System

Systems with multiple GPUs and CPUs are used in a variety of industries as developers expose and leverage more parallelism in applications such as artificial intelligence computing. High-performance GPU-accelerated systems with tens to many thousands of compute nodes are deployed in data centers, research facilities, and supercomputers to solve ever larger problems. As the number of processing devices within the high-performance systems increases, the communication and data transfer mechanisms need to scale to support the increased bandwidth.

FIG. 5B is a conceptual diagram of a processing system 500 implemented using the PPU 300 of FIG. 3, in accordance with an embodiment. The processing system 500 includes a CPU 530, switch 510, and multiple PPUs 300 each and respective memories 304. The NVLink 310 provides high-speed communication links between each of the PPUs 300. Although a particular number of NVLink 310 and interconnect 302 connections are illustrated in FIG. 5B, the number of connections to each PPU 300 and the CPU 530 may vary. The switch 510 interfaces between the interconnect 302 and the CPU 530. The PPUs 300, memories 304, and NVLinks 310 may be situated on a single semiconductor platform to form a parallel processing module 525. In an embodiment, the switch 510 supports two or more protocols to interface between various different connections and/or links.

In another embodiment (not shown), the NVLink 310 provides one or more high-speed communication links between each of the PPUs 300 and the CPU 530 and the switch 510 interfaces between the interconnect 302 and each of the PPUs 300. The PPUs 300, memories 304, and interconnect 302 may be situated on a single semiconductor platform to form a parallel processing module 525. In yet another embodiment (not shown), the interconnect 302 provides one or more communication links between each of the PPUs 300 and the CPU 530 and the switch 510 interfaces between each of the PPUs 300 using the NVLink 310 to provide one or more high-speed communication links between the PPUs 300. In another embodiment (not shown), the NVLink 310 provides one or more high-speed communication links between the PPUs 300 and the CPU 530 through the switch 510. In yet another embodiment (not shown), the interconnect 302 provides one or more communication links between each of the PPUs 300 directly. One or more of the NVLink 310 high-speed communication links may be implemented as a physical NVLink interconnect or either an on-chip or on-die interconnect using the same protocol as the NVLink 310.

In the context of the present description, a single semiconductor platform may refer to a sole unitary semiconductor-based integrated circuit fabricated on a die or chip. It should be noted that the term single semiconductor platform may also refer to multi-chip modules with increased connectivity which simulate on-chip operation and make substantial improvements over utilizing a conventional bus implementation. Of course, the various circuits or devices may also be situated separately or in various combinations of semiconductor platforms per the desires of the user. Alternately, the parallel processing module 525 may be implemented as a circuit board substrate and each of the PPUs 300 and/or memories 304 may be packaged devices. In an embodiment, the CPU 530, switch 510, and the parallel processing module 525 are situated on a single semiconductor platform.

In an embodiment, the signaling rate of each NVLink 310 is 20 to 25 Gigabits/second and each PPU 300 includes six NVLink 310 interfaces (as shown in FIG. 5B, five NVLink 310 interfaces are included for each PPU 300). Each NVLink 310 provides a data transfer rate of 25 Gigabytes/second in each direction, with six links providing 300 Gigabytes/second. The NVLinks 310 can be used exclusively for PPU-to-PPU communication as shown in FIG. 5B, or some combination of PPU-to-PPU and PPU-to-CPU, when the CPU 530 also includes one or more NVLink 310 interfaces.

In an embodiment, the NVLink 310 allows direct load/store/atomic access from the CPU 530 to each PPU's 300 memory 304. In an embodiment, the NVLink 310 supports coherency operations, allowing data read from the memories 304 to be stored in the cache hierarchy of the CPU 530, reducing cache access latency for the CPU 530. In an embodiment, the NVLink 310 includes support for Address Translation Services (ATS), allowing the PPU 300 to directly access page tables within the CPU 530. One or more of the NVLinks 310 may also be configured to operate in a low-power mode.

FIG. 5C illustrates an exemplary system 565 in which the various architecture and/or functionality of the various previous embodiments may be implemented.

As shown, a system 565 is provided including at least one central processing unit 530 that is connected to a communication bus 575. The communication bus 575 may be implemented using any suitable protocol, such as PCI (Peripheral Component Interconnect), PCI-Express, AGP (Accelerated Graphics Port), HyperTransport, or any other bus or point-to-point communication protocol(s). The system 565 also includes a main memory 540. Control logic (software) and data are stored in the main memory 540 which may take the form of random access memory (RAM).

The system 565 also includes input devices 560, the parallel processing system 525, and display devices 545, e.g., a conventional CRT (cathode ray tube), LCD (liquid crystal display), LED (light emitting diode), plasma display or the like. User input may be received from the input devices 560, e.g., keyboard, mouse, touchpad, microphone, and the like. Each of the foregoing modules and/or devices may even be situated on a single semiconductor platform to form the system 565. Alternately, the various modules may also be situated separately or in various combinations of semiconductor platforms per the desires of the user.

Further, the system 565 may be coupled to a network (e.g., a telecommunications network, local area network (LAN), wireless network, wide area network (WAN) such as the Internet, peer-to-peer network, cable network, or the like) through a network interface 535 for communication purposes.

The system 565 may also include a secondary storage (not shown). The secondary storage 610 includes, for example, a hard disk drive and/or a removable storage drive, representing a floppy disk drive, a magnetic tape drive, a compact disk drive, digital versatile disk (DVD) drive, recording device, universal serial bus (USB) flash memory. The removable storage drive reads from and/or writes to a removable storage unit in a well-known manner.

Computer programs, or computer control logic algorithms, may be stored in the main memory 540 and/or the secondary storage. Such computer programs, when executed, enable the system 565 to perform various functions. The memory 540, the storage, and/or any other storage are possible examples of computer-readable media.

The architecture and/or functionality of the various previous FIGURES may be implemented in the context of a general computer system, a circuit board system, a game console system dedicated for entertainment purposes, an application-specific system, and/or any other desired system. For example, the system 565 may take the form of a desktop computer, a laptop computer, a tablet computer, servers, supercomputers, a smart-phone (e.g., a wireless, hand-held device), personal digital assistant (PDA), a digital camera, a vehicle, a head mounted display, a hand-held electronic device, a mobile phone device, a television, workstation, game consoles, embedded system, and/or any other type of logic.

While various embodiments have been described above, it should be understood that they have been presented by way of example only, and not limitation. Thus, the breadth and scope of a preferred embodiment should not be limited by any of the above-described exemplary embodiments, but should be defined only in accordance with the following claims and their equivalents.

### Graphics Processing Pipeline

In an embodiment, the PPU 300 comprises a graphics processing unit (GPU). The PPU 300 is configured to receive commands that specify shader programs for processing graphics data. Graphics data may be defined as a set of primitives such as points, lines, triangles, quads, triangle strips, and the like. Typically, a primitive includes data that specifies a number of vertices for the primitive (e.g., in a model-space coordinate system) as well as attributes associated with each vertex of the primitive. The PPU 300 can be configured to process the graphics primitives to generate a frame buffer (e.g., pixel data for each of the pixels of the display).

An application writes model data for a scene (e.g., a collection of vertices and attributes) to a memory such as a system memory or memory 304. The model data defines each of the objects that may be visible on a display. The application then makes an API call to the driver kernel that requests the model data to be rendered and displayed. The driver kernel reads the model data and writes commands to the one or more streams to perform operations to process the model data. The commands may reference different shader programs to be implemented on the SMs 440 of the PPU 300 including one or more of a vertex shader, hull shader, domain shader, geometry shader, and a pixel shader. For example, one or more of the SMs 440 may be configured to execute a vertex shader program that processes a number of vertices defined by the model data. In an embodiment, the different SMs 440 may be configured to execute different shader programs concurrently. For example, a first subset of SMs 440 may be configured to execute a vertex shader program while a second subset of SMs 440 may be configured to execute a pixel shader program. The first subset of SMs 440 processes vertex data to produce processed vertex data and writes the processed vertex data to the L2 cache 460 and/or the memory 304. After the processed vertex data is rasterized (e.g., transformed from three-dimensional data into two-dimensional data in screen space) to produce fragment data, the second subset of SMs 440 executes a pixel shader to produce processed fragment data, which is then blended with other processed fragment data and written to the frame buffer in memory 304. The vertex shader program and pixel shader program may execute concurrently, processing different data from the same scene in a pipelined fashion until all of the model data for the scene has been rendered to the frame buffer. Then, the contents of the frame buffer are transmitted to a display controller for display on a display device.

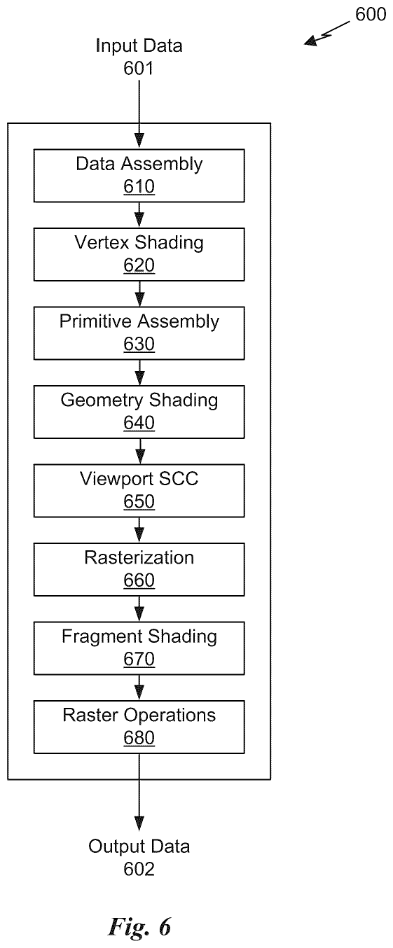

FIG. 6 is a conceptual diagram of a graphics processing pipeline 600 implemented by the PPU 300 of FIG. 3, in accordance with an embodiment. The graphics processing pipeline 600 is an abstract flow diagram of the processing steps implemented to generate 2D computer-generated images from 3D geometry data. As is well-known, pipeline architectures may perform long latency operations more efficiently by splitting up the operation into a plurality of stages, where the output of each stage is coupled to the input of the next successive stage. Thus, the graphics processing pipeline 600 receives input data 601 that is transmitted from one stage to the next stage of the graphics processing pipeline 600 to generate output data 602. In an embodiment, the graphics processing pipeline 600 may represent a graphics processing pipeline defined by the OpenGL® API. As an option, the graphics processing pipeline 600 may be implemented in the context of the functionality and architecture of the previous FIGURES and/or any subsequent Figure(s).

As shown in FIG. 6, the graphics processing pipeline 600 comprises a pipeline architecture that includes a number of stages. The stages include, but are not limited to, a data assembly stage 610, a vertex shading stage 620, a primitive assembly stage 630, a geometry shading stage 640, a viewport scale, cull, and clip (VSCC) stage 650, a rasterization stage 660, a fragment shading stage 670, and a raster operations stage 680. In an embodiment, the input data 601 comprises commands that configure the processing units to implement the stages of the graphics processing pipeline 600 and geometric primitives (e.g., points, lines, triangles, quads, triangle strips or fans, etc.) to be processed by the stages. The output data 602 may comprise pixel data (e.g., color data) that is copied into a frame buffer or other type of surface data structure in a memory.

The data assembly stage 610 receives the input data 601 that specifies vertex data for high-order surfaces, primitives, or the like. The data assembly stage 610 collects the vertex data in a temporary storage or queue, such as by receiving a command from the host processor that includes a pointer to a buffer in memory and reading the vertex data from the buffer. The vertex data is then transmitted to the vertex shading stage 620 for processing.

The vertex shading stage 620 processes vertex data by performing a set of operations (e.g., a vertex shader or a program) once for each of the vertices. Vertices may be, e.g., specified as a 4-coordinate vector (e.g., <x, y, z, w>) associated with one or more vertex attributes (e.g., color, texture coordinates, surface normal, etc.). The vertex shading stage 620 may manipulate individual vertex attributes such as position, color, texture coordinates, and the like. In other words, the vertex shading stage 620 performs operations on the vertex coordinates or other vertex attributes associated with a vertex. Such operations commonly including lighting operations (e.g., modifying color attributes for a vertex) and transformation operations (e.g., modifying the coordinate space for a vertex). For example, vertices may be specified using coordinates in an object-coordinate space, which are transformed by multiplying the coordinates by a matrix that translates the coordinates from the object-coordinate space into a world space or a normalized-device-coordinate (NCD) space. The vertex shading stage 620 generates transformed vertex data that is transmitted to the primitive assembly stage 630.

The primitive assembly stage 630 collects vertices output by the vertex shading stage 620 and groups the vertices into geometric primitives for processing by the geometry shading stage 640. For example, the primitive assembly stage 630 may be configured to group every three consecutive vertices as a geometric primitive (e.g., a triangle) for transmission to the geometry shading stage 640. In some embodiments, specific vertices may be reused for consecutive geometric primitives (e.g., two consecutive triangles in a triangle strip may share two vertices). The primitive assembly stage 630 transmits geometric primitives (e.g., a collection of associated vertices) to the geometry shading stage 640.

The geometry shading stage 640 processes geometric primitives by performing a set of operations (e.g., a geometry shader or program) on the geometric primitives. Tessellation operations may generate one or more geometric primitives from each geometric primitive. In other words, the geometry shading stage 640 may subdivide each geometric primitive into a finer mesh of two or more geometric primitives for processing by the rest of the graphics processing pipeline 600. The geometry shading stage 640 transmits geometric primitives to the viewport SCC stage 650.

In an embodiment, the graphics processing pipeline 600 may operate within a streaming multiprocessor and the vertex shading stage 620, the primitive assembly stage 630, the geometry shading stage 640, the fragment shading stage 670, and/or hardware/software associated therewith, may sequentially perform processing operations. Once the sequential processing operations are complete, in an embodiment, the viewport SCC stage 650 may utilize the data. In an embodiment, primitive data processed by one or more of the stages in the graphics processing pipeline 600 may be written to a cache (e.g., L1 cache, a vertex cache, etc.). In this case, in an embodiment, the viewport SCC stage 650 may access the data in the cache. In an embodiment, the viewport SCC stage 650 and the rasterization stage 660 are implemented as fixed function circuitry.

The viewport SCC stage 650 performs viewport scaling, culling, and clipping of the geometric primitives. Each surface being rendered to is associated with an abstract camera position. The camera position represents a location of a viewer looking at the scene and defines a viewing frustum that encloses the objects of the scene. The viewing frustum may include a viewing plane, a rear plane, and four clipping planes. Any geometric primitive entirely outside of the viewing frustum may be culled (e.g., discarded) because the geometric primitive will not contribute to the final rendered scene. Any geometric primitive that is partially inside the viewing frustum and partially outside the viewing frustum may be clipped (e.g., transformed into a new geometric primitive that is enclosed within the viewing frustum. Furthermore, geometric primitives may each be scaled based on a depth of the viewing frustum. All potentially visible geometric primitives are then transmitted to the rasterization stage 660.

The rasterization stage 660 converts the 3D geometric primitives into 2D fragments (e.g., capable of being utilized for display, etc.). The rasterization stage 660 may be configured to utilize the vertices of the geometric primitives to setup a set of plane equations from which various attributes can be interpolated. The rasterization stage 660 may also compute a coverage mask for a plurality of pixels that indicates whether one or more sample locations for the pixel intercept the geometric primitive. In an embodiment, z-testing may also be performed to determine if the geometric primitive is occluded by other geometric primitives that have already been rasterized. The rasterization stage 660 generates fragment data (e.g., interpolated vertex attributes associated with a particular sample location for each covered pixel) that are transmitted to the fragment shading stage 670.

The fragment shading stage 670 processes fragment data by performing a set of operations (e.g., a fragment shader or a program) on each of the fragments. The fragment shading stage 670 may generate pixel data (e.g., color values) for the fragment such as by performing lighting operations or sampling texture maps using interpolated texture coordinates for the fragment. The fragment shading stage 670 generates pixel data that is transmitted to the raster operations stage 680.

The raster operations stage 680 may perform various operations on the pixel data such as performing alpha tests, stencil tests, and blending the pixel data with other pixel data corresponding to other fragments associated with the pixel. When the raster operations stage 680 has finished processing the pixel data (e.g., the output data 602), the pixel data may be written to a render target such as a frame buffer, a color buffer, or the like.

It will be appreciated that one or more additional stages may be included in the graphics processing pipeline 600 in addition to or in lieu of one or more of the stages described above. Various implementations of the abstract graphics processing pipeline may implement different stages. Furthermore, one or more of the stages described above may be excluded from the graphics processing pipeline in some embodiments (such as the geometry shading stage 640). Other types of graphics processing pipelines are contemplated as being within the scope of the present disclosure. Furthermore, any of the stages of the graphics processing pipeline 600 may be implemented by one or more dedicated hardware units within a graphics processor such as PPU 300. Other stages of the graphics processing pipeline 600 may be implemented by programmable hardware units such as the SM 440 of the PPU 300.

The graphics processing pipeline 600 may be implemented via an application executed by a host processor, such as a CPU. In an embodiment, a device driver may implement an application programming interface (API) that defines various functions that can be utilized by an application in order to generate graphical data for display. The device driver is a software program that includes a plurality of instructions that control the operation of the PPU 300. The API provides an abstraction for a programmer that lets a programmer utilize specialized graphics hardware, such as the PPU 300, to generate the graphical data without requiring the programmer to utilize the specific instruction set for the PPU 300. The application may include an API call that is routed to the device driver for the PPU 300. The device driver interprets the API call and performs various operations to respond to the API call. In some instances, the device driver may perform operations by executing instructions on the CPU. In other instances, the device driver may perform operations, at least in part, by launching operations on the PPU 300 utilizing an input/output interface between the CPU and the PPU 300. In an embodiment, the device driver is configured to implement the graphics processing pipeline 600 utilizing the hardware of the PPU 300.

Various programs may be executed within the PPU 300 in order to implement the various stages of the graphics processing pipeline 600. For example, the device driver may launch a kernel on the PPU 300 to perform the vertex shading stage 620 on one SM 440 (or multiple SMs 440). The device driver (or the initial kernel executed by the PPU 400) may also launch other kernels on the PPU 400 to perform other stages of the graphics processing pipeline 600, such as the geometry shading stage 640 and the fragment shading stage 670. In addition, some of the stages of the graphics processing pipeline 600 may be implemented on fixed unit hardware such as a rasterizer or a data assembler implemented within the PPU 400. It will be appreciated that results from one kernel may be processed by one or more intervening fixed function hardware units before being processed by a subsequent kernel on an SM 440.

### Machine Learning

Deep neural networks (DNNs) developed on processors, such as the PPU 300 have been used for diverse use cases, from self-driving cars to faster drug development, from automatic image captioning in online image databases to smart real-time language translation in video chat applications. Deep learning is a technique that models the neural learning process of the human brain, continually learning, continually getting smarter, and delivering more accurate results more quickly over time. A child is initially taught by an adult to correctly identify and classify various shapes, eventually being able to identify shapes without any coaching. Similarly, a deep learning or neural learning system needs to be trained in object recognition and classification for it get smarter and more efficient at identifying basic objects, occluded objects, etc., while also assigning context to objects.

At the simplest level, neurons in the human brain look at various inputs that are received, importance levels are assigned to each of these inputs, and output is passed on to other neurons to act upon. An artificial neuron or perceptron is the most basic model of a neural network. In one example, a perceptron may receive one or more inputs that represent various features of an object that the perceptron is being trained to recognize and classify, and each of these features is assigned a certain weight based on the importance of that feature in defining the shape of an object.

A deep neural network (DNN) model includes multiple layers of many connected nodes (e.g., perceptrons, Boltzmann machines, radial basis functions, convolutional layers, etc.) that can be trained with enormous amounts of input data to quickly solve complex problems with high accuracy. In one example, a first layer of the DNN model breaks down an input image of an automobile into various sections and looks for basic patterns such as lines and angles. The second layer assembles the lines to look for higher level patterns such as wheels, windshields, and mirrors. The next layer identifies the type of vehicle, and the final few layers generate a label for the input image, identifying the model of a specific automobile brand.

Once the DNN is trained, the DNN can be deployed and used to identify and classify objects or patterns in a process known as inference. Examples of inference (the process through which a DNN extracts useful information from a given input) include identifying handwritten numbers on checks deposited into ATM machines, identifying images of friends in photos, delivering movie recommendations to over fifty million users, identifying and classifying different types of automobiles, pedestrians, and road hazards in driverless cars, or translating human speech in real-time.

During training, data flows through the DNN in a forward propagation phase until a prediction is produced that indicates a label corresponding to the input. If the neural network does not correctly label the input, then errors between the correct label and the predicted label are analyzed, and the weights are adjusted for each feature during a backward propagation phase until the DNN correctly labels the input and other inputs in a training dataset. Training complex neural networks requires massive amounts of parallel computing performance, including floating-point multiplications and additions that are supported by the PPU 300. Inferencing is less compute-intensive than training, being a latency-sensitive process where a trained neural network is applied to new inputs it has not seen before to classify images, translate speech, and generally infer new information.

Neural networks rely heavily on matrix math operations, and complex multi-layered networks require tremendous amounts of floating-point performance and bandwidth for both efficiency and speed. With thousands of processing cores, optimized for matrix math operations, and delivering tens to hundreds of TFLOPS of performance, the PPU 300 is a computing platform capable of delivering performance required for deep neural network-based artificial intelligence and machine learning applications. It is noted that the techniques described herein may be embodied in executable instructions stored in a computer readable medium for use by or in connection with a processor-based instruction execution machine, system, apparatus, or device. It will be appreciated by those skilled in the art that, for some embodiments, various types of computer-readable media can be included for storing data. As used herein, a “computer-readable medium” includes one or more of any suitable media for storing the executable instructions of a computer program such that the instruction execution machine, system, apparatus, or device may read (or fetch) the instructions from the computer-readable medium and execute the instructions for carrying out the described embodiments. Suitable storage formats include one or more of an electronic, magnetic, optical, and electromagnetic format. A non-exhaustive list of conventional exemplary computer-readable medium includes: a portable computer diskette; a random-access memory (RAM); a read-only memory (ROM); an erasable programmable read only memory (EPROM); a flash memory device; and optical storage devices, including a portable compact disc (CD), a portable digital video disc (DVD), and the like.

It should be understood that the arrangement of components illustrated in the attached FIGURES are for illustrative purposes and that other arrangements are possible. For example, one or more of the elements described herein may be realized, in whole or in part, as an electronic hardware component. Other elements may be implemented in software, hardware, or a combination of software and hardware. Moreover, some or all of these other elements may be combined, some may be omitted altogether, and additional components may be added while still achieving the functionality described herein. Thus, the subject matter described herein may be embodied in many different variations, and all such variations are contemplated to be within the scope of the claims.

To facilitate an understanding of the subject matter described herein, many aspects are described in terms of sequences of actions. It will be recognized by those skilled in the art that the various actions may be performed by specialized circuits or circuitry, by program instructions being executed by one or more processors, or by a combination of both. The description herein of any sequence of actions is not intended to imply that the specific order described for performing that sequence must be followed. All methods described herein may be performed in any suitable order unless otherwise indicated herein or otherwise clearly contradicted by context.

The use of the terms “a” and “an” and “the” and similar references in the context of describing the subject matter (particularly in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. Furthermore, the foregoing description is for the purpose of illustration only, and not for the purpose of limitation, as the scope of protection sought is defined by the claims as set forth hereinafter together with any equivalents thereof. The use of any and all examples, or exemplary language (e.g., “such as”) provided herein, is intended merely to better illustrate the subject matter and does not pose a limitation on the scope of the subject matter unless otherwise claimed. The use of the term “based on” and other like phrases indicating a condition for bringing about a result, both in the claims and in the written description, is not intended to foreclose any other conditions that bring about that result. No language in the specification should be construed as indicating any non-claimed element as essential to the practice of the invention as claimed.

What is claimed is:

1. A power distribution board (PDB), the PDB comprising:
a supply input unit to receive power at a supply voltage;
a power converter to convert the power received at a supply voltage to an operating voltage of a graphics processing unit (GPU); and
one or more GPU power connectors to provide power directly to one or more GPUs at the operating voltage.

2. The PDB of claim 1, wherein the PDB is a mid-chassis PDB configured to be mounted in a middle region of a data center server chassis.

3. The PDB of claim 1, wherein the power converter comprises a dual-regulated, hybrid switched capacitor (DR-HSC).

4. The PDB of claim 1, further comprising a GPU interconnect board power connector to provide power directly to a GPU interconnect board at the operating voltage.

5. The PDB of claim 1, wherein the supply voltage is greater than or equal to 48V and the operating voltage is less than or equal to 12V.

6. The PDB of claim 1, wherein the one or more GPU power connectors include at least one of a blade power connector or a pin power connector.

7. The PDB of claim 6, wherein the pin power connector is a PCI Express (PCIe) 5.0 CEM (Card Electromechanical) (“CEM5”) pin power connector.

8. A power supply and distribution system, comprising:
one or more power supply units (PSUs) to supply power at a supply voltage;
one or more busbars to transmit the power at the supply voltage; and
a power distribution board (PDB) configured to receive the power at the supply voltage from the one or more busbars, the PDB comprising:
a supply input unit to receive the power at the supply voltage;
a power converter to convert the power received at the supply voltage to an operating voltage of a graphics processing unit (GPU); and
one or more GPU power connectors to provide power directly to one or more GPUs at the operating voltage.

9. The power supply and distribution system of claim 8, wherein a PSU of the one or more PSUs comprises:
a power supply PDB; and
one or more common redundant power supplies (CRPSs) to supply the power at the supply voltage and connected to the power supply PDB.

10. The power supply and distribution system of claim 9, wherein a CRPS of the one or more CRPSs is to receive alternating current (AC) power from one or more external power distribution units (PDUs) and to supply the power at the supply voltage by converting the AC power to direct current (DC) power at the supply voltage.

11. The power supply and distribution system of claim 10, wherein the received AC power has a distribution voltage of 230V or higher.

12. The power supply and distribution system of claim 8, wherein the PDB is a mid-chassis PDB configured to be mounted in a middle region of a data center server chassis.

13. The power supply and distribution system of claim 8, wherein the power converter comprises a dual-regulated, hybrid switched capacitor (DR-HSC).

14. The power supply and distribution system of claim 8, further comprising a GPU interconnect board power connector to provide power directly to a GPU interconnect board at the operating voltage.

15. A server, comprising:
one or more GPUs;
one or more power supply units (PSUs) to supply power at a supply voltage;
one or more busbars to transmit the power at the supply voltage; and
a power distribution board (PDB) configured to receive the power at the supply voltage from the one or more busbars and distribute power at an operating voltage to the one or more GPUs, the PDB comprising:
a supply input unit to receive the power at the supply voltage;
a power converter to convert the power received at the supply voltage to the operating voltage; and
one or more GPU power connectors to provide power directly to one or more GPUs at the operating voltage.

16. The server of claim 15, wherein the one or more GPUs have an aggregated total board power (TBP) and the one or more busbars have an aggregated cross-sectional area, wherein a ratio of the aggregated cross-sectional area to the aggregated TBP is less than 10 mm²/kW.

17. The server of claim 16, wherein the ratio of the aggregated cross-sectional area to the aggregated TBP is less than 8 mm²/kW.

18. The server of claim 16, wherein the ratio of the aggregated cross-sectional area to the aggregated TBP is in a range of 4.5 mm²/kW to 8 mm²/kW.

19. The server of claim 15, wherein the PDB is a mid-chassis PDB configured to be mounted in a middle region of a data center server chassis.

20. The server of claim 15, wherein the server is comprised in at least one of:
a control system for an autonomous or semi-autonomous machine;
a perception system for an autonomous or semi-autonomous machine;
a system for performing simulation operations;
a system for performing digital twin operations;
a system for performing light transport simulation;
a system for performing collaborative content creation for 3D assets;
a system for performing deep learning operations;
a system implemented using an edge device;
a system implemented using a robot;
a system for performing conversational AI operations;
a system for generating synthetic data;
a system incorporating one or more virtual machines (VMs);
a system implemented at least partially in a data center; or
a system implemented at least partially using cloud computing resources.
